(19) United States
(12) Patent Application Publication
(10) Pub. No.: US 2025/0107160 A1
(43) Pub. Date: Mar. 27, 2025

(54) TRANSISTOR AND DEVICE

(71) Applicant: SAMSUNG ELECTRONICS CO., LTD., Suwon-si (KR)

(72) Inventors: Joonseok Kim, Suwon-si (KR); Sangwon KIM, Suwon-si (KR); CHANG SEOK LEE, Suwon-si (KR); Huije Ryu, Suwon-si (KR); KEUN WOOK SHIN, Suwon-si (KR)

(21) Appl. No.: 18/625,801

(22) Filed: Apr. 3, 2024

(30) Foreign Application Priority Data
Sep. 27, 2023 (KR) 10-2023-0131068

(51) Int. Cl. H01L 29/76

(52) U.S. Cl. CPC H10D 48/362

(57) ABSTRACT

A transistor including a semiconductor channel including a compound semiconductor, and a source electrode and a drain electrode each electrically connected to the semiconductor channel and each independently including a topological conductor, wherein the compound semiconductor and the topological conductor include at least one metal element in common.

### CROSS-REFERENCE TO RELATED APPLICATION

This application claims priority to and the benefit of Korean Patent Application No. 10-2023-0131068 filed in the Korean Intellectual Property Office on Sep. 27, 2023, the entire contents of which are incorporated herein by reference.

### BACKGROUND OF THE INVENTION

### (a) Field of the Invention

The present disclosure relates to a transistor and an electronic device.

### (b) Description of the Related Art

Transistors are major components configuring circuits in electronic devices such as semiconductor devices or display devices. Recently, reducing the size of each component, including transistors, has been important for implementing highly integrated, high-performance semiconductor devices or high-resolution display panels. Accordingly, research is being conducted to reduce the line width through scaling of each part, such as metal wiring, electrodes, semiconductor channels, and interconnects.

### SUMMARY OF THE INVENTION

However, due to the scaling, electrodes with narrow line widths in the nanometer level may cause a rapid increase in resistance due to physical and material limitations, which may deteriorate the performance of the device.

An embodiment provides a transistor capable of reducing or preventing performance deterioration due to the scaling.

Another embodiment provides a device including the transistor.

Another embodiment provides an electronic device including the device.

According to an embodiment, a transistor including: a semiconductor channel including a compound semiconductor; and a source electrode and a drain electrode each electrically connected to the semiconductor channel and each independently including a topological conductor, wherein the compound semiconductor and the topological conductor include at least one metal element in common is provided.

The at least one metal element may include molybdenum, tungsten, tantalum, niobium, cobalt, titanium, iron, manganese, gallium, hafnium, zinc, vanadium, indium, nickel, tin, platinum, chromium, copper, ruthenium, aluminum, zirconium, rhodium, thallium, iridium, palladium, rhenium, cadmium, osmium, or lead.

The compound semiconductor may be represented by Chemical Formula 1, and the topological conductor may be represented by Chemical Formula 2

Mₐ(XₑY₁₋ₑ)_{b} Chemical Formula 1

M_{c}(Y_{f}X_{1-f})_{d} Chemical Formula 2
wherein, in Chemical Formula 1 and Chemical Formula 2,
each M may be independently at least one metal element,
each X may be independently S, Se, Te, O, N, or P,
each Y may be independently different from X and may be at least one of S, Se, Te, C, N, P, As, Sb, or Si,
and 0<a≤10, 0<b≤10, 0<c≤10, 0<d≤10, 0.7<e≤1 and 0.7<f≤1.

The compound semiconductor may be represented by Chemical Formula 1-1, and the topological conductor may be represented by Chemical Formula 2

MₐX_{b}. Chemical Formula 1-1

The compound semiconductor may be represented by Chemical Formula 1, and the topological conductor may be represented by Chemical Formula 2-1

M_{c}Y_{d}. Chemical Formula 2-1

The compound semiconductor may be represented by Chemical Formula 1-1, and the topological conductor may be represented by Chemical Formula 2-1.

The compound semiconductor represented by Chemical Formula 1-1 may include at least one of CuS, MoS₂, MoSe₂, MoSSe, MoSTe, Mo₁₋ₓWₓS₂, Mo₁₋ₓWₓSe₂, Mo₁₋ₓWₓTe₂, Mo₁₋ₓNbₓS₂, Mo₁₋ₓNbₓSe₂, Mo₁₋ₓTaₓS₂, Mo₁₋ₓTaₓSe₂, Mo₁₋ₓWₓSSe, MoTe₂, WS₂, WSe₂, WSSe, WTe₂, WSTe, W₁₋ₓNbₓS₂, W₁₋ₓNbₓSe₂, PtS₂, PtSe₂, PtTe₂, PdSe₂, TaS₂, TaSe₂, Ta₁₋ₓWₓS₂, Ta₁₋ₓWₓSe₂, CoPS₃, CrPS₄, Cu₁₋ₓCrₓP₂S₆, NiPS₃, Ta₂O₅, Ta₃N₅, TaON, or Nb₂O₅ wherein x in each of the foregoing is independently 0≤x≤1, and the topological conductor represented by Chemical Formula 2-1 may include at least one of MoP, MoTe₂, MoC, MoN, WC, WN, WTe₂, TaN, TaAs, TaP, TaSb₂, NbN, NbS, NbP, NbAs, ZrTe, or Cd₃As₂.

The compound semiconductor may include a one-dimensional, two-dimensional, or three-dimensional semiconducting material, and the topological conductor may include a one-dimensional or two-dimensional conductive material.

A change in resistivity of the topological conductor resulting from a 10% reduction in line width may be less than about 2 times relative to a resistivity of the topological conductor without the 10% reduction in line width.

A difference between a resistivity of the topological conductor with a line width of about 3 nanometers (nm) and a resistivity of the topological conductor with a line width of about 40 nm may be less than about 10 times the resistivity of the topological conductor with the 40 nm line width.

The source electrode and the drain electrode may each independently have a width of about 0.1 nm to about 100 nm.

The semiconductor channel, the source electrode, and the drain electrode may each independently have a thickness of about 0.1 nm to about 20 nm.

At least one of a lower portion, upper portion, or side portion of each of the source electrode and the drain electrode may be in contact with the semiconductor channel.

The compound semiconductor and the topological conductor may have the same or different crystal structures, and an interface between the semiconductor channel and the source electrode or the drain electrode may have a continuous crystal structure including the at least one metal element.

The source electrode may include a first source electrode and a second source electrode, and the drain electrode may include a first drain electrode and a second drain electrode, wherein the first source electrode and the first drain electrode are each in contact with the semiconductor channel and each independently includes the topological conductor, and the second source electrode and the second drain electrode are each in contact with the first source electrode and the first drain electrode, respectively, and each independently includes a metal or metal alloy different from the at least one metal element of the topological conductor.

A thickness of the first source electrode and a thickness of the first drain electrode may each independently be about 1 nm to about 20 nm, respectively, and a thickness of the second source electrode and a thickness of the second drain electrode may be greater than the thickness of the first source electrode or the thickness of the first drain electrode.

The transistor may further include a gate electrode disposed on the semiconductor channel, and a gate insulating layer between the semiconductor channel and the gate electrode.

According to another embodiment, a device including the transistor is provided.

The device may include a semiconductor device or a display device.

According to another embodiment, an electronic device including the device is provided.

It is possible to reduce or prevent performance deterioration by lowering the contact resistance and refining a scaling of the electrode.

### BRIEF DESCRIPTION OF THE DRAWINGS

FIG. 1 is a cross-sectional view of an embodiment showing an example of a transistor.

FIGS. 2 to 12 are each a perspective view of an embodiment showing examples of various structures of a semiconductor channel and source/drain electrodes of a transistor.

### DETAILED DESCRIPTION OF THE EMBODIMENTS

Example embodiments of the present disclosure will hereinafter be described in detail, and may be easily performed by a person having an ordinary skill in the related art. However, the present disclosure may be embodied in many different forms, and should not be construed as limited to the example embodiments set forth herein. Rather, these embodiments are provided so that this disclosure will be thorough and complete, and will fully convey the scope of the invention to those skilled in the art. The terms used herein are merely for the purpose of describing example embodiments, and are not intended to limit the present disclosure. As used herein, the singular forms are intended to include the plural forms unless the context clearly indicates otherwise. For example, “an element” has the same meaning as “at least one element,” unless the context clearly indicates otherwise. Thus, reference to “an” element in a claim followed by reference to “the” element is inclusive of one element and a plurality of the elements. “At least one” is not to be construed as limiting “a” or “an.” “Or” means “and/or.” As used herein, the term “and/or” includes any and all combinations of one or more of the associated listed items.

Throughout the specification, the terms “comprise” or “have” are intended to specify the presence of stated features, integers, steps, operations, constituent elements, components or a combination thereof, but do not preclude the presence or addition of one or more other features, integers, steps, operations, constituent elements, components, and/or groups thereof.

In the drawings, the thickness of layers and regions may be exaggerated for clarity, and like reference numerals designate like elements throughout the specification. It will be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present.

The drawings and description are to be regarded as illustrative in nature and not restrictive. Like reference numerals designate like elements throughout the specification.

It will be understood that when a component is referred to as being “on” or “over” another component, the component can be directly on, under, on the left of, or on the right of the other component, or can be on, under, on the left of, or on the right of the other component in a non-contact manner. In addition, unless explicitly described to the contrary, the word “comprise”, and variations such as “comprises” or “comprising”, will be understood to imply the inclusion of stated elements but not the exclusion of any other elements.

The term “layer” includes a construction having a shape formed on a part of a region, in addition to a construction having a shape formed on an entire region.

As used herein, the term “the” or similar indicative terms correspond to both the singular form and the plural form. the steps of all methods described herein can be performed in any suitable order unless otherwise indicated herein or otherwise clearly contradicted by context.

Also, terms such as “unit.” “module,” etc., as used in the present specification may refer to a part for processing at least one function or action and may be implemented as hardware, software, or a combination of hardware and software.

The connecting lines, or connectors shown in the various figures presented are intended to represent example functional relationships and/or physical or logical couplings between the various elements. It should be noted that many alternative or additional functional relationships, physical connections or logical connections may be present in a practical apparatus.

As used herein, “at least one of A, B, and C”, “at least one of A, B, or C”, “one of A, B, C, or a combination thereof”, and “one of A, B, C, and a combination thereof” refer to each constituent element, and a combination thereof (e.g., A; B; C; A and B; A and C; B and C; or A, B and C).

Here, “a combination thereof” refer to a mixture, a stacked structure, a composite, an alloy, or a blend.

Hereinafter, unless otherwise defined, “substantially” or “approximately” or “about” includes not only the stated value, but also the average within an allowable range of deviation, considering the error associated with the measurement and amount of the measurement.

For example, “substantially” or “approximately” may mean within ±10%, ±5%, 3%, or ±1% of the indicated value or within a standard deviation. All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.).

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, “metal” is interpreted as a concept including metals and metalloids (semimetals).

Hereinafter, an example of a transistor according to an embodiment will be described with reference to the drawings.

In an aspect, a transistor, comprises: a semiconductor channel comprising a compound semiconductor; and a source electrode and a drain electrode each electrically connected to the semiconductor channel and each independently comprising a topological conductor, wherein the compound semiconductor and the topological conductor comprise at least one metal element in common.

The source electrode and the drain electrode “each independently” comprising the topological conductor herein may refer to the source electrode and the drain electrode comprising a same topological conductor or a different topological conductor.

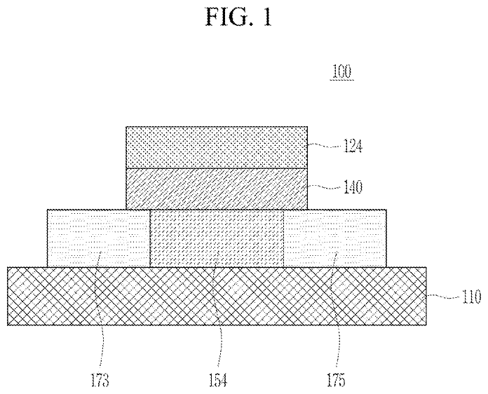

FIG. 1 is a cross-sectional view showing an example of a transistor according to an embodiment.

Referring to FIG. 1, a transistor 100 according to an embodiment includes a gate electrode 124, a gate insulating layer 140, a semiconductor channel 154, and a source electrode 173 and a drain electrode 175 (e.g., source/drain electrodes 173 and 175).

A substrate 110 may be a support substrate that supports the transistor 100, and may be, for example, a semiconductor substrate, a polymer substrate, a metal substrate, or a glass substrate.

The semiconductor substrate may include, for example, Group IV elements such as Si, Ge and/or Sn; compound semiconductors including Group Ill-V semiconductors and/or Group II-VI semiconductors; or a combination thereof. “Group” means a group of the Periodic Table of the Elements according to the International Union of Pure and Applied Chemistry (“IUPAC”) Group 1-18 group classification system. Group Ill-V semiconductor may refer to a semiconductor comprising a Group Ill element and a Group V element. Group II-VI semiconductor may refer to a semiconductor comprising a Group II element and a Group VI element.

The polymer substrate may include, for example, at least one of polyethylene terephthalate, polyethylene naphthalate, polycarbonate, polyacrylate, polymethylmethacrylate, polyimide, polyamide, polyamideimide, copolymers thereof, but is not limited thereto. For example, the substrate 110 may include at least one of Si, Ge, C, Zn, Cd, Al, Ga, In, B, C, N, P, S, Se, As, Sb, Te Ta, Ru, Rh, Ir, Co, Ta, Ti, W, Pt, Au, Ni, or Fe. The substrate 110 may include a single layer or multiple layers of different materials stacked. For example, the substrate 110 may be a silicon-on-insulator (SOI) substrate or a silicon germanium-on-insulator (SGOI) substrate. For example, the substrate 110 may include N and/or F in a SiCOH composition, and may include pores to lower the dielectric constant.

The gate electrode 124 is electrically connected to a gate line (not shown) configured to transmit a gate signal. The gate electrode 124 may be disposed on (e.g., overlap) a semiconductor channel 154, which will be described later, along a thickness direction of the substrate 110. The gate electrode 124 may include a low-resistance conductor, such as at least one of copper, molybdenum, aluminum, nickel, gold, chromium, and tantalum, or titanium, an alloy thereof, but is not limited thereto. The gate electrode 124 may have one or two or more layers.

The gate insulating layer 140 is interposed between the gate electrode 124 and a semiconductor channel 154 to be described later. The gate insulating layer 140 may include an organic material, an inorganic material, and/or an organic-inorganic material, for example, oxide, nitride, and/or oxynitride, such as at least one of silicon oxide, silicon nitride, silicon oxynitride, or aluminum oxide, but is not limited thereto. The gate insulating layer 140 may have one or two or more layers.

The semiconductor channel 154 and the source/drain electrodes 173 and 175 are disposed on a same plane on the substrate 110. However, this only shows an example of a coplanar structure, and is not limited thereto.

The semiconductor channel 154 is positioned between the source/drain electrodes 173 and 175, and each of the source/drain electrodes 173 and 175 is electrically connected to the semiconductor channel 154. For example, the semiconductor channel 154 may be in contact with the source/drain electrodes 173 and 175, respectively. For example, one side of the semiconductor channel 154 may be in contact with the source electrode 173, and the other side of the semiconductor channel 154 may be in contact with the drain electrode 175.

The semiconductor channel 154 may include a compound semiconductor. The compound semiconductor may include, for example, at least one metal element and at least one metalloid element and/or non-metal element. In an aspect, the compound semiconductor may include at least one metal element. The compound semiconductor may be a single crystalline or polycrystalline compound with a predetermined crystal structure, for example, a zinc blende structure or a hexagonal close packed lattice (HCP), but is not limited thereto.

The compound semiconductor may be a one-dimensional, two-dimensional, or three-dimensional semiconducting material, such as a one-dimensional, two-dimensional, or three-dimensional semiconducting nanomaterial. The one-dimensional semiconducting nanomaterial may be a linear semiconducting nanomaterial extending along one axis (e.g., x-axis). For example, a length extending along the x-axis may be about 100 nm or less. The two-dimensional semiconducting nanomaterial may be a planar semiconducting nanomaterial that extends along two axes (e.g., x-axis and y-axis), and for example, at least one of a length along the x-axis or a length along the y-axis may be 100 nm or less. A three-dimensional semiconducting nanomaterial may be a three-dimensional semiconducting nanomaterial that extends along three axes (e.g., x-axis, y-axis, and z-axis), and for example, at least one of a length along the x-axis, a length along the y-axis, or a length along the z-axis may be 100 nm or less. The compound semiconductor may be, for example, at least one of a nanowire, nanorod, nanotube, nanoflake, nanosheet, or nanoparticle. For example, the nanosheet may have a layered crystal structure or a structure in which one or two or more atomic layers are stacked. For example, a nanosheet may have a structure in which 1 to 10 atomic layers are stacked.

The source/drain electrodes 173 and 175 may include the topological conductor. The topological conductor is also referred to as a topological metal, and may further include at least one metal element and optionally a metalloid element and/or a non-metal element. The topological conductor may be different from the compound semiconductor included in the semiconductor channel 154. The topological conductor may be a single crystal or polycrystalline compound with a predetermined crystal structure, for example, a hexagonal close packed lattice (HCP), but is not limited thereto. The crystal structure of the topological conductor may be the same as or different from the crystal structure of the compound semiconductor included in the semiconductor channel 154.

The topological conductor may be a one-dimensional or two-dimensional semiconducting material, such as at least one of a nanowire, nanorod, nanotube, nanoflake, or nanosheet. For example, a nanosheet may have a layered crystal structure or a structure in which one or two or more atomic layers are stacked. For example, the nanosheet may have a structure in which 1 to 20 atomic layers are stacked.

Unlike bulk metals, topological conductors have less electron scattering at the surface and/or grain boundaries, so even if the surface area to volume ratio increases, a rapid increase in resistivity may not occur.

For example, in copper electrodes containing copper Cu as a main component, one of the common bulk metals, the transport of electrons may be affected by the increase in electron scattering on the metal surface and/or grain boundaries due to (e.g., resulting from) a decrease in line width. Especially when the line width narrows to a nanometer level of about 10 nm or less, such an effect may drastically increase, leading to a rapid increase in the resistivity of the copper electrode and a possible performance degradation due to heat generation.

On the contrary, as mentioned above, topological conductors may have very little or no change in resistivity due to the reduction in line width, as electron scattering is less on the surface and/or grain boundary as described above. In particular, a rapid increase in resistivity may not be observed even when the line width narrows to the nanometer level of about 10 nm or less. For example, a change in resistivity of the topological conductor due to a decrease in line width of about 10% may be less than about 2 times, and may be about 1.8 times or less, about 1.5 times or less, or about 1.2 times or less, or greater than about 1 to less than about 2 times, relative to a resistivity of the topological conductor without the 10% reduction in line width. In an aspect, the change in resistivity of the topological conductor resulting from the 10% reduction in line width is less than about 2 times relative to a resistivity of the topological conductor without the 10% reduction in line width. For example, the change in resistivity of the topological conductor due to line width reduction may be compared with a resistivity of a topological conductor with a line width of about 3 nm and a resistivity of a topological conductor with a line width of about 40 nm. A difference in a resistivity of the topological conductor with a line width of about 3 nm and a resistivity of the topological conductor with a line width of about 40 nm may be less than about 10 times, and may be about 8 times or less, about 7 times or less, about 5 times or less, about 3 times or less, about 2 times or less, about 1.8 times or less, about 1.5 times or less, or about 1.2 times or less, or greater than about 1 to less than about 10 times the resistivity of the topological conductor with the 40 nm line width. This is significantly less than the resistivity of copper with a line width of about 3 nm, which is about 20 times greater than that of copper with a line width of about 40 nm.

Therefore, the source/drain electrodes 173 and 175 may prevent a rapid increase in resistivity and reduce or prevent performance degradation due to heat generation, even when they have a fine line width at the nanometer level of about 10 nm or less, by including the topological conductor.

Meanwhile, the compound semiconductor included in the semiconductor channel 154 and the topological conductor included in the source/drain electrodes 173 and 175 may include at least one metal element in common.

The at least one metal element is not particularly limited as long as it is a metal that may configure a compound semiconductor and a topological conductor in common, for example, at least one of molybdenum (Mo), tungsten (W), tantalum (Ta), niobium (Ni), cobalt (Co), Titanium (Ti), iron (Fe), manganese (Mn), gallium (Ga), hafnium (Hf), zinc (Zn), vanadium (V), indium (In), nickel (Ni), tin (Sn), Platinum (Pt), chromium (Cr), copper (Cu), ruthenium (Ru), aluminum (Al), zirconium (Zr), rhodium (Rh), thallium (TI), iridium (Ir), palladium (Pd), rhenium (Re), cadmium (Cd), osmium (Os), or lead (Pb), but is not limited thereto.

For example, the compound semiconductor included in the semiconductor channel 154 may be represented by Chemical Formula 1, and the topological conductor included in the source/drain electrodes 173 and 175 may be represented by Chemical Formula 2:

Mₐ(XₑY₁₋ₑ)_{b} Chemical Formula 1

M_{c}(Y_{f}X_{1-f})_{d} Chemical Formula 2
wherein, in Chemical Formula 1 and Chemical Formula 2,
each M may be independently at least one metal element, such as molybdenum, tungsten, tantalum, niobium, cobalt, titanium, iron, manganese, gallium, hafnium, zinc, vanadium, indium, nickel, tin, platinum, chromium, copper, ruthenium, aluminum, zirconium, rhodium, thallium, iridium, palladium, rhenium, cadmium, osmium, or lead,
each X may be independently at least one of S, Se, Te, O, N, or P,
each Y may be independently different from X, and may be at least one of S, Se, Te, C, N, P, As, Sb, or Si,
and 0<a≤10, 0<b≤10, 0<c≤10, 0<d≤10, 0.7<e≤1 and 0.7<f≤1.

As shown in Chemical Formula 1 and Chemical Formula 2, the compound semiconductor included in the semiconductor channel 154 and the topological conductor included in the source/drain electrodes 173 and 175 may include at least one metal element M in common and each may independently further include a metalloid element and/or a non-metal element represented by X and/or Y. Here, a ratio (atomic ratio) (e, f) of X and Y may vary depending on the manufacturing method of the semiconductor channel 154 and the source/drain electrodes 173 and 175, and may be determined depending on a degree of substitution and bonding numbers, etc. For example, e in Chemical Formula 1 may be 0.75≤e≤1, 0.8≤e≤1, 0.85≤e≤1, 0.9≤e≤1, 0.95≤e≤1, 0.97≤e≤1, 0.99≤e≤1, or e=1. For example, f in Chemical Formula 2 may be 0.75≤f≤1, 0.8≤f≤1, 0.85≤f≤1, 0.9≤f≤1, 0.95≤f≤1, 0.97≤f≤1, 0.99≤f≤1 or f=1.

For example, the metal element M may be deposited on the substrate 110 to form a metal pattern, then a portion of the metal pattern is supplied (e.g., doped) with the X element, and heat-treated to form the semiconductor channel 154 including the compound semiconductor. Then, the Y element may be supplied (e.g., doped) to another portion of the metal pattern, and heat-treated to form the source/drain electrodes 173 and 175 including the topological conductor. Here, the region where the X element is supplied (e.g., doped) may be the semiconductor channel 154, which includes the compound semiconductor with a crystal structure that includes the substitution of part of the metal element M with the X element or the combination of the metal element M and the X element. The region where the Y element is supplied (e.g., doped) may be the source/drain electrodes 173 and 175, which include the topological conductor with a crystal structure that includes the substitution of part of the metal element M with the Y element or the combination of the metal element M and the Y element. The substitution of elements and the combination between elements may be confirmed through changes in color and texture observed using a microscope, changes in Raman spectrum through X-ray diffraction (XRD) analysis, and/or elemental analysis through energy dispersive spectrometer (EDS) analysis. At this time, the compound semiconductor included in the semiconductor channel 154 may be represented by Chemical Formula 1-1, and the topological conductor included in the source/drain electrodes 173 and 175 may be expressed by Chemical Formula 2-1

MₐX_{b} Chemical Formula 1-1

M_{c}Y_{d} Chemical Formula 2-1
wherein in Chemical Formula 1-1 and Chemical Formula 2-1, each M, X, Y, and a to d are as described above.

For example, the compound semiconductor represented by MₐX_{b} may be deposited on the substrate 110 to form a semiconductor pattern, and then a portion of the semiconductor pattern may be supplied (e.g., doped) with the Y element and heat treated to form the source/drain electrodes 173 and 175 including the topological conductor. Here, the region where the Y element is not supplied may be the semiconductor channel 154, which includes the compound semiconductor represented by MₐX_{b}, and the region where the Y element is supplied may be the source/drain electrodes 173 and 175, which includes the topological conductor with a crystal structure that includes a combination of X element and Y element, or where at least a part of the X element is replaced with Y element.

At this time, the compound semiconductor included in the semiconductor channel 154 may be represented by Chemical Formula 1-1, and the topological conductor included in the source/drain electrodes 173 and 175 may be represented by Chemical Formula 2.

For example, the topological conductor represented by M_{c}Y_{d} may be deposited on the substrate 110 to form a conductive pattern, and then a portion of the conductive pattern may be supplied (e.g., doped) with the X element and heat treated to form the semiconductor channel 154 including the compound semiconductor. Here, the region where the X element is not supplied may be the source/drain electrodes 173 and 175, which includes the topological conductor represented by M_{c}Y_{d}, and the region where the X element is supplied (e.g., doped) may be the semiconductor channel 154, which includes the compound semiconductor with a crystal structure that includes a combination of X element and Y element, or where at least a part of the Y element is replaced with X element. At this time, the compound semiconductor included in the semiconductor channel 154 may be represented by Chemical Formula 1, and the topological conductor included in the source/drain electrodes 173 and 175 may be represented by Chemical Formula 2-1.

For example, a metal oxide including the metal element M may be deposited on the substrate 110 to form a metal oxide pattern, then a portion of the metal oxide pattern is supplied (e.g., doped) with the X element, and heat-treated to form the semiconductor channel 154 including the compound semiconductor. Then, the Y element may be supplied (e.g., doped) to another portion of the metal oxide pattern, and heat-treated to form the source/drain electrodes 173 and 175 including the topological conductor. Here, the region where the X element is supplied (e.g., doped) may be the semiconductor channel 154, which includes the compound semiconductor with a crystal structure including the substitution of part of the metal element M and/or oxygen element with the X element or the combination of the metal element M and the X element. The region where the Y element is supplied (e.g., doped) may be the source/drain electrodes 173 and 175, which include the topological conductor with a crystal structure including the substitution of part of the metal element M and/or oxygen element with the Y element or the combination of the metal element M and the Y element. At this time, the compound semiconductor included in the semiconductor channel 154 may be represented by Chemical Formula 1-1, and the topological conductor included in the source/drain electrodes 173 and 175 may be represented by Chemical Formula 2-1.

For example, the compound semiconductor represented by MₐX_{b} may be deposited on the substrate 110 to form a semiconductor pattern, and then the Y element may be supplied (e.g., doped) on both sides of the semiconductor pattern and grown by heat-treatment, thereby forming the source/drain electrodes 173 and 175 that includes the topological conductor represented by M_{c}Y_{d}. Here, the region to which the Y element is not supplied may be the semiconductor channel 154 including the compound semiconductor represented by MₐX_{b}.

For example, the topological conductor represented by M_{c}Y_{d} may be deposited on the substrate 110 to form two separated conductive patterns, which are then heat-treated and grown by supplying (e.g., doping) the X element between the two conductive patterns to form the semiconductor channel 154 including the compound semiconductor represented by MₐX_{b}. Here, the two separated conductive patterns may be the source/drain electrodes 173 and 175 each independently including the topological conductor represented by M_{c}Y_{d}.

For example, the compound semiconductor represented by Chemical Formula 1-1 may include at least one of CuS, MoS₂, MoSe₂, MoSSe, MoSTe, Mo₁₋ₓWₓS₂, Mo₁₋ₓWₓSe₂, Mo₁₋ₓWₓTe₂, Mo₁₋ₓNbₓS₂, Mo₁₋ₓNbₓSe₂, Mo₁₋ₓTaₓS₂, Mo₁₋ₓTaₓSe₂, Mo₁₋ₓWₓSSe, MoTe₂, WS₂, WSe₂, WSSe, WTe₂, WSTe, W₁₋ₓNbₓS₂, W₁₋ₓNbₓSe₂, PtS₂, PtSe₂, PtTe₂, PdSe₂, TaS₂, TaSe₂, Ta₁₋ₓWₓS₂, Ta₁₋ₓWₓSe₂, CoPS₃, CrPS₄, Cu₁₋ₓCrₓP₂S₆, NiPS₃, Ta₂O₅, Ta₃N₅, TaON, or Nb₂O₅ (wherein x in each of the forgoing is independently 0≤x≤1), but is not limited thereto.

For example, the topological conductor represented by Chemical Formula 2-1 may include at least one of MoP, MoTe₂, MoC, MoN, WC, WN, WTe₂, TaN, TaAs, TaP, TaSb₂, NbN, NbS, NbP, NbAs, ZrTe, or Cd₃As₂, but is not limited thereto.

The source/drain electrodes 173 and 175 may have a narrow width of several nanometers to tens of nanometers, considering the advantages of the above-mentioned topological conductor. For example, a width of each of the source/drain electrodes 173 and 175 may be independently less than about 100 nm, and may be greater than or equal to about 0.1 nm and less than about 100 nm, about 0.1 nm to about 80 nm, about 0.1 nm to about 60 nm, about 0.1 nm to about 50 nm, and about 0.1 nm to about 40 nm, about 0.1 nm to about 30 nm, about 0.1 nm to about 20 nm, about 0.1 nm to about 10 nm, about 0.1 nm to about 8 nm, about 0.1 nm to about 7 nm, about 0.1 nm to about 5 nm, greater than or equal to about 1 nm and less than about 100 nm, about 1 nm to about 80 nm, about 1 nm to about 60 nm, about 1 nm to about 50 nm, about 1 nm to about 40 nm, about 1 nm to about 30 nm, about 1 nm to about 20 nm, about 1 nm to about 10 nm, about 1 nm to about 8 nm, about 1 nm to about 7 nm, or about 1 nm to about 5 nm. A width of the semiconductor channel 154 may also be in the same range as above.

A thickness of the source/drain electrodes 173 and 175 may each independently be about 1000 nm or less, and may be about 0.1 nm to about 1000 nm, about 0.1 nm to about 800 nm, about 0.1 nm to about 600 nm, about 0.1 nm to about 500 nm, about 0.1 nm to about 300 nm, about 0.1 nm to about 200 nm, about 0.1 nm to about 100 nm, about 0.1 nm to about 80 nm, about 0.1 nm to about 50 nm, about 0.1 nm to about 30 nm, about 0.1 nm to about 20 nm, about 0.1 nm to about 10 nm, about 1 nm to about 1000 nm, about 1 nm to about 800 nm, about 1 nm to about 600 nm, about 1 nm to about 500 nm, about 1 nm to about 300 nm, about 1 nm to about 200 nm, about 1 nm to about 100 nm, about 1 nm to about 80 nm, about 1 nm to about 50 nm, about 1 nm to about 30 nm, about 1 nm to about 20 nm or about 1 nm to about 10 nm. A thickness of the semiconductor channel 154 may also be in the same range as above.

The semiconductor channel 154 and the source/drain electrodes 173 and 175 may have the same or different crystal structures. An interface between the semiconductor channel 154 and the source/drain electrodes 173 and 175 may have a continuous crystal structure made of a common metal element by including at least one metal element in common. In an aspect, the compound semiconductor and the topological conductor have the same or different crystal structures. In an aspect, the interface between the semiconductor channel and the source electrode or the drain electrode has a continuous crystal structure comprising the at least one metal element. Accordingly, the semiconductor channel 154 and the source/drain electrodes 173 and 175 may form a continuous interface and have a substantially seamless interface, thereby lowering contact resistance.

In addition, by forming an integrated pattern (e.g., the metal pattern, semiconductor pattern, or conductive pattern described above) for forming the semiconductor channel 154 and the source/drain electrodes 173 and 175, and substituting or growing additional elements, the semiconductor channel 154 and the source/drain electrodes 173 and 175 may be formed in a single exposure process, reducing processing costs and shortening processing time.

In addition, as described above, the source/drain electrodes 173 and 175 may prevent a rapid increase in resistivity and reduce or prevent performance degradation due to heat generation, even when they have a fine line width of about 10 nm or less, by including the topological conductor.

While FIG. 1 illustrates an exemplary structure in which the source/drain electrodes 173 and 175 are in contact with a side portion of the semiconductor channel 154, the present disclosure is not limited thereto. At least one of a lower, upper, or side portion of each of the source electrode 173 and the drain electrode 175 may be in contact with the semiconductor channel 154.

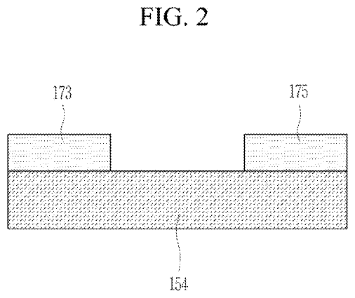

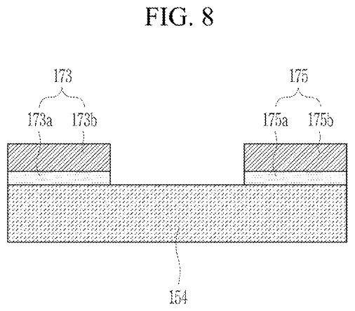

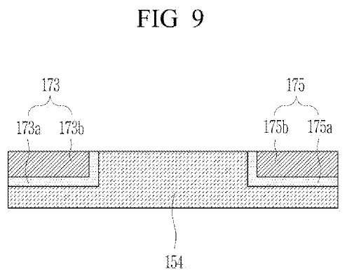

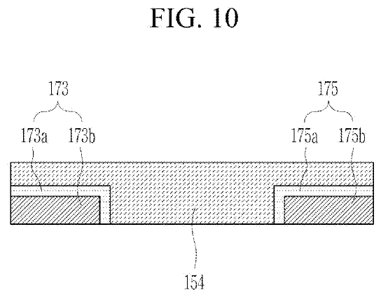

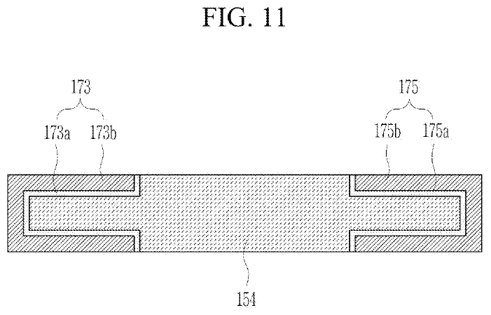

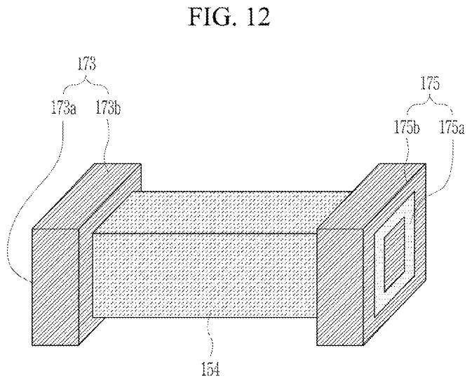

FIGS. 2 to 12 are each a perspective view of an embodiment showing examples of various structures of the semiconductor channel and source/drain electrodes of the transistor.

Referring to FIG. 2, the source/drain electrodes 173 and 175 are positioned on the semiconductor channel 154, and each lower portion of the source/drain electrodes 173 and 175 may be in contact with the upper portion of the semiconductor channel 154.

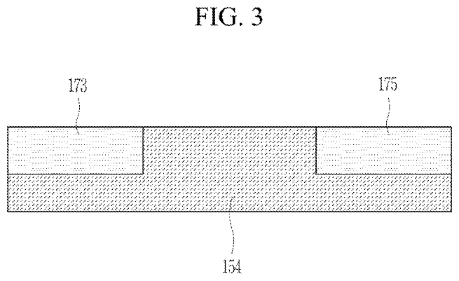

Referring to FIG. 3, the semiconductor channel 154 includes portions with different thicknesses, and the lower and side portions of the source/drain electrodes 173 and 175 may be in contact with the upper and side portions of the semiconductor channel 154.

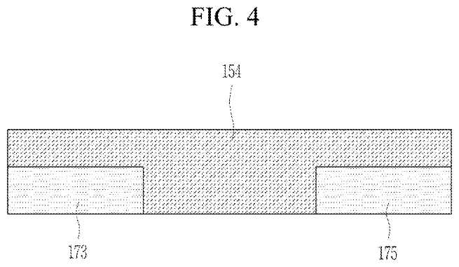

Referring to FIG. 4, the semiconductor channel 154 includes portions with different thicknesses, and the upper and side portions of the source/drain electrodes 173 and 175 may be in contact with the lower and side portions of the semiconductor channel 154.

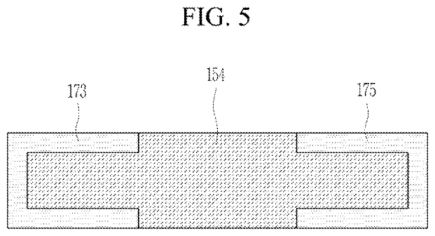

Referring to FIG. 5, the semiconductor channel 154 includes portions with different thicknesses, and the upper, lower, and side portions of the source/drain electrodes 173 and 175 may be in contact with the lower, upper, and side portions of the semiconductor channel 154.

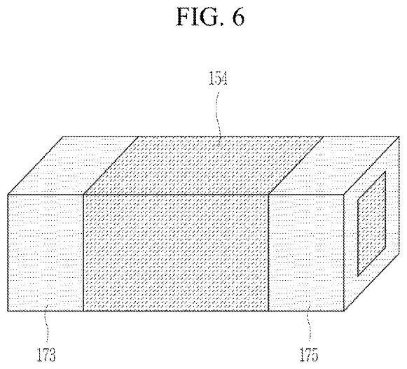

Referring to FIG. 6, the source/drain electrodes 173 and 175 may surround a portion of the semiconductor channel 154, and the upper, lower, and side portions of the source/drain electrodes 173 and 175 may be in contact with the lower, upper, and side portions of the semiconductor channel 154.

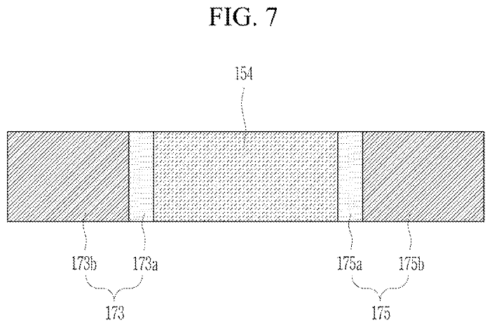

Referring to FIGS. 7 to 12, the source/drain electrodes 173 and 175 include first source/drain electrodes 173a and 175a and second source/drain electrodes 173b and 175b.

The first source/drain electrodes 173a and 175a are in contact with the semiconductor channel 154 and may include the above-described topological conductor. Therefore, the interface of the first source/drain electrodes 173a and 175a and the semiconductor channel 154 may have a continuous crystal structure made of a common metal element by including at least one metal element in common. Accordingly, the first source/drain electrodes 173a and 175a and the semiconductor channel 154 may form a continuous interface and have a substantially seamless interface, thereby lowering contact resistance.

The second source/drain electrodes 173b and 175b are in contact with the first source/drain electrodes 173a and 175a, and may include a conductor different from the topological conductor included in the first source/drain electrodes 173a and 175a. For example, the second source/drain electrodes 173b and 175b may include bulk metal or an alloy thereof, such as at least one of copper, molybdenum, aluminum, nickel, gold, chromium, tantalum, titanium, an alloy thereof, but is not limited thereto.

In an aspect, the source electrode comprises a first source electrode and a second source electrode, and the drain electrode comprises a first drain electrode and a second drain electrode, wherein the first source electrode and the first drain electrode are each in contact with the semiconductor channel and each independently comprises the topological conductor, and the second source electrode and the second drain electrode are each in contact with the first source electrode and the first drain electrode, respectively, and each independently comprises a metal or metal alloy different from the at least one metal element of the topological conductor.

Each of the second source/drain electrodes 173b and 175b may be thicker than at least one of the first source/drain electrodes 173a and 175a. For example, thickness of the second source/drain electrodes 173b and 175b may each independently be about 2 to about 100 times the thickness of at least one of the first source/drain electrodes 173a and 175a. In an aspect, a thickness of the first source electrode and a thickness of the first drain electrode are each independently about 1 nm to about 20 nm, and a thickness of the second source electrode and a thickness of the second drain electrode are each independently greater than the thickness of the first source electrode or the thickness of the first drain electrode. For example, the first source/drain electrodes 173a and 175a may have a thickness of about 1 nm to about 20 nm, and the second source/drain electrodes 173b and 175b may have a thickness of about 50 nm to about 1 μm.

As such, the source/drain electrodes 173 and 175 may include the first source/drain electrode 173a and 175a including the topological conductor and the second source/drain electrode 173b and 175b including the bulk metal or the alloy thereof, thereby reducing the contact resistance of the semiconductor channel 154 with the first source/drain electrode 173a and 175a, providing a low resistance electrode.

In FIGS. 2 to 12, the substrate 110, gate electrode 124, and gate insulating layer 140 of FIG. 1 are omitted, but the substrate 110 may be positioned under the semiconductor channel 154 and the source/drain electrodes 173 and 175 as a support substrate, and the gate electrode 124 may be disposed on (e.g., overlaid on, or overlap) the semiconductor channel 154 with the gate insulating layer 140 interposed therebetween. In an aspect, the transistor further comprises the gate electrode disposed on the semiconductor channel, and the gate insulating layer located between the semiconductor channel and the gate electrode.

The above-described transistor 100 may be, for example, a metal-oxide-semiconductor field-effect transistor (MOSFET), fin field-effect transistor (FinFET), gate-all-around field-effect transistor (GAAFET), multi-bridge channel field-effect transistor (MBCFET), complementary field-effect transistor (CFET), or vertical field-effect transistor (VFET), and an integrated circuit including the transistor may be included in a semiconductor device.

The transistor 100 described above may be a thin film transistor (TFT), and a thin film transistor array including the same may be included in a display device.

The semiconductor devices or display devices may be included in various electronic devices, such as computers, mobile phones, video phones, smart phones, tablet personal computers (PCs), laptop PCs, computer monitors, smart watches, digital cameras, televisions, e-books, and personal digital assistants (PDAs), portable multimedia players (PMPs), enterprise digital assistants (EDAs), head mounted displays (HMDs), vehicle navigations, internet of things loT devices, internet of everything loE devices, drones, door locks, safes, automated teller machines (ATMs), security devices, medical devices, or automotive electrical components, etc., but are not limited thereto.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A transistor, comprising:
a semiconductor channel comprising a compound semiconductor; and
a source electrode and a drain electrode each electrically connected to the semiconductor channel and each independently comprising a topological conductor,
wherein the compound semiconductor and the topological conductor comprise at least one metal element in common.

2. The transistor of claim 1, wherein the at least one metal element comprises molybdenum, tungsten, tantalum, niobium, cobalt, titanium, iron, manganese, gallium, hafnium, zinc, vanadium, indium, nickel, tin, platinum, chromium, copper, ruthenium, aluminum, zirconium, rhodium, thallium, iridium, palladium, rhenium, cadmium, osmium, or lead.

3. The transistor of claim 1, wherein
the compound semiconductor is represented by Chemical Formula 1, and
the topological conductor is represented by Chemical Formula 2
Mₐ(XₑY₁₋ₑ)_{b} Chemical Formula 1
M_{c}(Y_{f}X_{1-f})_{d} Chemical Formula 2
wherein, in Chemical Formula 1 and Chemical Formula 2,
each M is independently at least one metal element,
each X is independently at least one of S, Se, Te, O, N, or P,
each Y is independently different from X and is at least one of S, Se, Te, C, N, P, As, Sb, or Si, and
0<a≤10, 0<b≤10, 0<c≤10, 0<d≤10, 0.7<e≤1 and 0.7<f≤1.

4. The transistor of claim 1, wherein
the compound semiconductor is represented by Chemical Formula 1-1, and
the topological conductor is represented by Chemical Formula 2
MₐX_{b} Chemical Formula 1-1
M_{c}(Y_{f}X_{1-f})_{d} Chemical Formula 2
wherein, in Chemical Formula 1-1 and Chemical Formula 2,
each M is independently at least one metal element,
each X is independently at least one of S, Se, Te, O, N, or P,
each Y independently is different from X and is at least one of S, Se, Te, C, N, P, As, Sb, or Si, and
0<a≤10, 0<b≤10, 0<c≤10, 0<d≤10 and 0.7<f≤1.

5. The transistor of claim 1, wherein
the compound semiconductor is represented by Chemical Formula 1, and
the topological conductor is represented by Chemical Formula 2-1
Mₐ(XₑY₁₋ₑ)_{b} Chemical Formula 1
M_{c}Y_{d} Chemical Formula 2-1
wherein, in Chemical Formula 1 and Chemical Formula 2-1,
each M is independently at least one metal element,
each X is independently at least one of S, Se, Te, O, N, or P,
each Y is independently different from X and is at least one of S, Se, Te, C, N, P, As, Sb, or Si, and
0<a≤10, 0<b≤10, 0<c≤10, 0<d≤10 and 0.7<e≤1.

6. The transistor of claim 1, wherein
the compound semiconductor is represented by Chemical Formula 1-1, and
the topological conductor is represented by Chemical Formula 2-1
MₐX_{b} Chemical Formula 1-1
M_{c}Y_{d} Chemical Formula 2-1
wherein, in Chemical Formula 1-1 and Chemical Formula 2-1,
each M is independently at least one metal element,
each X is independently at least one of S, Se, Te, O, N, or P,
each Y is independently different from X and is at least one of S, Se, Te, C, N, P, As, Sb, or Si, and
0<a≤10, 0<b≤10, 0<c≤10 and 0<d≤10.

7. The transistor of claim 6, wherein
the compound semiconductor represented by Chemical Formula 1-1 comprises at least one of CuS, MoS₂, MoSe₂, MoSSe, MoSTe, Mo₁₋ₓWₓS₂, Mo₁₋ₓWₓSe₂, Mo₁₋ₓWₓTe₂, Mo₁₋ₓNbₓS₂, Mo₁₋ₓNbₓSe₂, Mo₁₋ₓTaₓS₂, Mo₁₋ₓTaₓSe₂, Mo₁₋ₓWₓSSe, MoTe₂, WS₂, WSe₂, WSSe, WTe₂, WSTe, W₁₋ₓNbₓS₂, W₁₋ₓNbₓSe₂, PtS₂, PtSe₂, PtTe₂, PdSe₂, TaS₂, TaSe₂, Ta₁₋ₓWₓS₂, Ta₁₋ₓWₓSe₂, CoPS₃, CrPS₄, Cu₁₋ₓCrₓP₂S₆, NiPS₃, Ta₂O₅, Ta₃N₅, TaON, Nb₂O₅, wherein x in each of the foregoing is independently 0≤x≤1.

8. The transistor of claim 6, wherein the topological conductor represented by Chemical Formula 2-1 comprises at least one of MoP, MoTe₂, MoC, MoN, WC, WN, WTe₂, TaN, TaAs, TaP, TaSb₂, NbN, NbS, NbP, NbAs, ZrTe, or Cd₃As₂.

9. The transistor of claim 1, wherein
the compound semiconductor comprises a one-dimensional, two-dimensional, or three-dimensional semiconducting material, and
the topological conductor comprises a one-dimensional or two-dimensional conductive material.

10. The transistor of claim 1, wherein a change in a resistivity of the topological conductor resulting from a 10% reduction in line width is less than about 2 times relative to a resistivity of the topological conductor without the 10% reduction in line width.

11. The transistor of claim 1, wherein a difference between a resistivity of the topological conductor with a 3 nanometers line width and a resistivity of the topological conductor with a 40 nm line width is less than about 10 times the resistivity of the topological conductor with the 40 nanometers line width.

12. The transistor of claim 1, wherein the source electrode and the drain electrode each independently have a width of about 0.1 nanometer to about 100 nanometers.

13. The transistor of claim 1, wherein the semiconductor channel, the source electrode, and the drain electrode each independently have a thickness of about 0.1 nanometer to about 20 nanometers.

14. The transistor of claim 1, wherein at least one of a lower portion, upper portion, or side portion of each of the source electrode and the drain electrode is in contact with the semiconductor channel.

15. The transistor of claim 1, wherein
the compound semiconductor and the topological conductor have the same or different crystal structures, and
an interface between the semiconductor channel and the source electrode or the drain electrode has a continuous crystal structure comprising the at least one metal element.

16. The transistor of claim 1, wherein the source electrode comprises a first source electrode and a second source electrode, and the drain electrode comprises a first drain electrode and a second drain electrode, wherein
the first source electrode and the first drain electrode are each in contact with the semiconductor channel and each independently comprises the topological conductor, and
the second source electrode and the second drain electrode are each in contact with the first source electrode and the first drain electrode, respectively, and each independently comprises a metal or metal alloy different from the at least one metal element of the topological conductor.

17. The transistor of claim 16, wherein
a thickness of the first source electrode and a thickness of the first drain electrode are each independently about 1 nanometer to about 20 nanometers, and
a thickness of the second source electrode and a thickness of the second drain electrode are each independently greater than the thickness of the first source electrode or the thickness of the first drain electrode.

18. The transistor of claim 1, further comprising
a gate electrode disposed on the semiconductor channel, and
a gate insulating layer located between the semiconductor channel and the gate electrode.

19. A device comprising the transistor of claim 1.

20. The device of claim 19, wherein the device is a semiconductor device or a display device.
